(19) United States
(12) Patent Application Publication
(10) Pub. No.: US 2025/0179625 A1
(43) Pub. Date: Jun. 5, 2025

(54) METHOD OF FORMING SILICON NITRIDE FILM AND FILM FORMING APPARATUS

(71) Applicant: Tokyo Electron Limited, Tokyo (JP)

(72) Inventors: Munehito KAGAYA, Tokyo (JP); Yusuke SUZUKI, Yamanashi (JP); Yuji OTSUKI, Albany, NY (US)

(21) Appl. No.: 18/836,916

(22) PCT Filed: Feb. 3, 2023
(86) PCT No.: PCT/JP2023/003599

§ 371 Date: Aug. 8, 2024

(30) Foreign Application Priority Data
Feb. 15, 2022 (JP) 2022-021561

(51) Int. Cl. C23C 16/02; C23C 16/34; C23C 16/455; H01J 37/32; H01L 21/02

(52) U.S. Cl. CPC C23C 16/0272; C23C 16/345; C23C 16/45534; H01J 37/32449; H01L 21/0217; H01L 21/02274; H01L 21/0228; H01J 2237/332

(57) ABSTRACT

A method of forming a silicon nitride film and a film forming apparatus in which a silicon nitride film can be embedded in a recess are provided. A method of forming a silicon nitride film in a recess formed on a surface of a substrate, the method including: a process of forming an adsorption-inhibiting region by exposing the substrate to a plasma generated from an adsorption-inhibiting gas containing at least one of a halogen gas or a non-halogen gas; a process of adsorbing a silicon-containing gas to a region other than the adsorption-inhibiting region; and a process of forming a silicon nitride film by exposing the substrate to which the silicon-containing gas is adsorbed to plasma generated from a nitrogen-containing gas, wherein a cycle including the process of forming the adsorption-inhibiting region, the process of adsorbing the silicon-containing gas, and the process of forming the silicon nitride film is repeated, and in the process of forming the adsorption-inhibiting region, with an increase in a count of repetition of the cycle, a state in which adsorption inhibition by the halogen gas is high changes to a state in which adsorption inhibition by the non-halogen gas is high.

### TECHNICAL FIELD

The present disclosure relates to a method of forming a silicon nitride film, and to a film forming apparatus.

### BACKGROUND ART

Patent Document 1 discloses a method of forming a silicon nitride film. The method includes: a process of supplying an ammonia-containing gas to a substrate having a depression formed on a surface and nitriding the surface of the depression to form an adsorption site in the depression; a process of supplying a chlorine-containing gas to the substrate and causing the chlorine-containing gas to be physically adsorbed in a predetermined region from the uppermost portion of the depression to a predetermined depth to form a non-adsorption site in the predetermined region; and a process of supplying a silicon-containing gas to the substrate and causing the silicon-containing gas to be adsorbed on the adsorption site including a bottom remaining in the depression other than the predetermined region to form a silicon nitride film by reaction between the ammonia-containing gas and the silicon-containing gas.

### CITATION LIST

### Patent Literature

Patent Document 1: Japanese Laid-Open Patent Publication No. 2018-10950

### SUMMARY OF INVENTION

### Technical Problem

The present disclosure provides a method of forming a silicon nitride film and a film forming apparatus in which a silicon nitride film can be embedded in a recess.

### Solution to Problem

One aspect of the present disclosure provides: a method of forming a silicon nitride film. The method includes: a process of forming an adsorption-inhibiting region by exposing the substrate to a plasma generated from an adsorption-inhibiting gas containing at least one of a halogen gas or a non-halogen gas; a process of adsorbing a silicon-containing gas to a region other than the adsorption-inhibiting region; and a process of forming a silicon nitride film by exposing the substrate to which the silicon-containing gas is adsorbed to a plasma generated from a nitrogen-containing gas, wherein a cycle including the process of forming the adsorption-inhibiting region, the process of adsorbing the silicon-containing gas, and the process of forming the silicon nitride film is repeated, and in the process of forming the adsorption-inhibiting region, with an increase in a count of repetition of the cycle, a state in which adsorption inhibition by the halogen gas is high changes to a state in which adsorption inhibition by the non-halogen gas is high.

### Advantageous Effects of Invention

According to the present disclosure, it is possible to provide a method of forming a silicon nitride film and a film forming apparatus in which a silicon nitride film can be embedded in a recess.

### BRIEF DESCRIPTION OF THE DRAWINGS

FIG. 1 is a schematic cross-sectional diagram illustrating an example of a film forming apparatus according to an embodiment;

FIG. 2 is a flowchart illustrating an example of a method of forming a silicon nitride film according to a first embodiment;

FIG. 3A is an example of a cross-sectional schematic diagram illustrating a change in aspect ratio of a recess when a SiN film is embedded in the recess;

FIG. 3B is an example of a cross-sectional schematic diagram illustrating a change in aspect ratio of a recess when a SiN film is embedded in the recess;

FIG. 3C is an example of a cross-sectional schematic diagram illustrating a change in aspect ratio of a recess when a SiN film is embedded in the recess;

FIG. 3D is an example of a cross-sectional schematic diagram illustrating a change in aspect ratio of a recess when a SiN film is embedded in the recess;

FIG. 4 is an example of a graph illustrating a relationship between a number of cycles of a film forming process of SiN film and the aspect ratio of the recess;

FIG. 5 is an example of a graph explaining a concentration distribution of an adsorption-inhibiting gas in the recess;

FIG. 6 is an example of a graph explaining an inhibition effect by the adsorption-inhibiting gas;

FIG. 7 is a flowchart illustrating an example of a method of forming a silicon nitride film according to a second embodiment;

FIG. 8A is an example of a graph illustrating a change in an adjustment parameter as the number of cycles increases;

FIG. 8B is an example of a graph illustrating a change in an adjustment parameter as the number of cycles increases;

FIG. 9 is a flowchart illustrating an example of a method of forming a silicon nitride film according to a third embodiment;

FIG. 10 is an example of a graph illustrating a change in an adjustment parameter as the number of cycles increases;

FIG. 11 is a flowchart illustrating an example of a method of forming a silicon nitride film according to a fourth embodiment; and

FIG. 12 is a flowchart illustrating an example of a method of forming a silicon nitride film according to a fifth embodiment.

### DESCRIPTION OF EMBODIMENTS

In the following, a non-limiting exemplary embodiment of the present disclosure will be described with reference to the accompanying drawings. In all the accompanying drawings, the same or corresponding members or parts will be denoted by the same or corresponding reference numerals, and repeated explanations will be omitted.

### Film Forming Apparatus

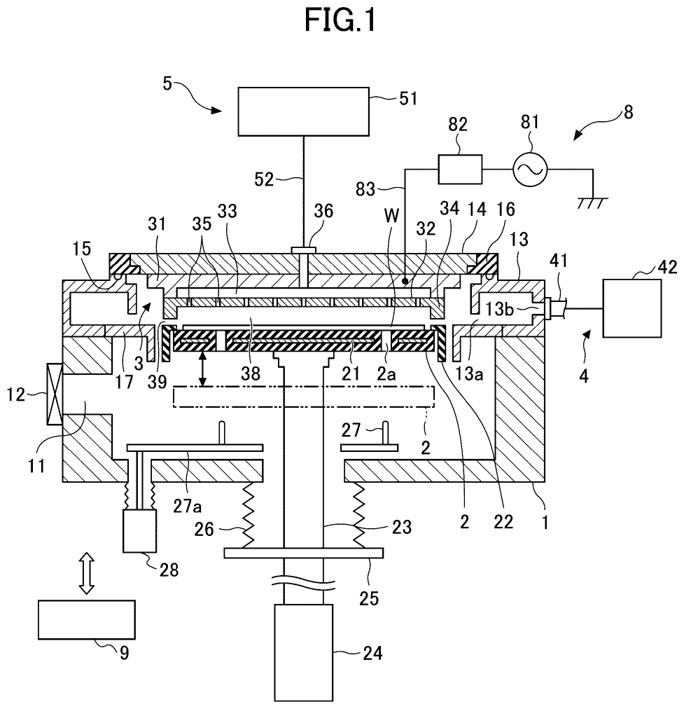

Referring to FIG. 1, an example of a film forming apparatus of an embodiment will be described. The film forming apparatus includes a processing container 1, a mounting table 2, a shower head 3, an exhaust 4, a gas supply 5, an RF power supply 8, a 30 controller 9, and the like.

The processing container 1 is made of a metal such as aluminum and has a substantially cylindrical shape. The processing container 1 accommodates a wafer W as an example of a substrate. A loading/unloading port 11 for loading/unloading the wafer w is formed on the side wall of the processing 1. The loading/unloading port 11 is container opened/closed by a gate valve 12. An annular exhaust duct 13 having a rectangular cross section is provided on the main body of the processing container 1. A slit 13a is formed along the inner peripheral surface of the exhaust duct 13. An exhaust port 13b is formed on the outer wall of the exhaust duct 13. A ceiling wall 14 is provided on the upper surface of the exhaust duct 13 so as to close the upper opening of the processing container 1 via an insulator member 16. A seal ring 15 creates an airtight seal between the exhaust duct 13 and the insulator member 16. A partitioning member 17 partitions the inside of the processing container 1 vertically when the mounting table 2 (and a cover member 22) rise to a processing position described later.

The mounting table 2 horizontally supports the wafer W in the processing container 1. The mounting table 2 is formed in a disk shape having a size corresponding to the wafer W and is supported by a support member 23. The mounting table 2 is formed of a ceramic material such as AlN or a metal material such as aluminum or nickel alloy. A heater 21 for heating the wafer W is embedded in the mounting table 2. The heater 21 generates heat by receiving power from a heater power source (not illustrated). The wafer W is controlled to a predetermined temperature by controlling the output of the heater 21 according to a temperature signal of a thermocouple (not illustrated) provided near the upper surface of the mounting table 2. The mounting table 2 is provided with a cover member 22 made of ceramics such as alumina so as to cover the outer peripheral region of the upper surface and the side surface of the mounting table 2.

The support member 23 for supporting the mounting table 2 is provided on the bottom surface of the mounting table 2. The support member 23 extends from the center of the bottom surface of the mounting table 2 through a hole formed in the bottom wall of the processing container 1 to below the processing container 1. The lower end of the support member 23 is connected to a lifting mechanism 24. The lifting mechanism 24 raises and lowers the mounting table 2 via the support member 23 between a processing position illustrated in FIG. 1 and a transport position at which the wafer W is transportable, wherein the transport position is indicated by an alternate long and two short dashes line below the processing position. Below the processing container 1, a flange 25 is mounted on the support member 23.

A bellows 26 is provided between the bottom surface of the processing container 1 and the flange 25. The bellows 26 partitions the atmosphere in the processing container 1 from the external air, and expands and in response contracts to the raised/lowered movement of the mounting table 2.

Three wafer support pins 27 (of which only two are illustrated) are provided in the vicinity of the bottom surface of the processing container 1 to protrude upward from a lifting plate 27a. The wafer support pins 27 are raised and lowered through the lifting plate 27a by the lifting mechanism 28 provided below the processing container 1. The wafer support pins 27 are inserted through the through holes 2a provided in the mounting table 2 located at the transport position and are configured to protrude and retract with respect to the upper surface of the mounting table 2. By raising/lowering the wafer support pins 27, the wafer W is delivered between a transport mechanism (not illustrated) and the mounting table 2.

The shower head 3 supplies a processing gas into the processing container 1 in a shower form. The shower head 3 is made of a metal, is provided to face the mounting table 2, and has a diameter that is substantially the same as that of the mounting table 2. The shower head 3 includes a main body 31 and a shower plate 32. The main body 31 is fixed to the ceiling wall 14 of the processing container 1. The shower plate 32 is connected under the main body 31. A gas diffusion space 33 is formed between the main body 31 and the shower plate 32. The gas diffusion space 33 is provided with a gas introduction hole 36 which penetrates the centers of the ceiling wall 14 of the processing container 1, and the main body 31. An annular protrusion 34 protruding downward is formed on the peripheral edge of the shower plate 32. Gas ejection holes 35 are formed in a flat portion inside the annular protrusion 34. In the state in which the mounting table 2 is present at the processing position, a processing space 38 is formed between the mounting table 2 and the shower plate 32, and the top surface of the cover member 22 and the annular protrusion 34 are close to each other to form an annular gap 39 therebetween.

The exhaust 4 evacuates the interior of the processing container 1. The exhaust 4 includes an exhaust pipe 41 connected to the exhaust port 13b, and an exhaust mechanism 42 connected to the exhaust pipe 41 and including a vacuum pump, a pressure control valve, and the like. During the processing, the gas in the processing container 1 reaches the exhaust duct 13 via the slit 13a, and is exhausted from the exhaust duct 13 through the exhaust pipe 41 by the exhaust mechanism 42.

The gas supply 5 supplies various types of processing gases to the shower head 3. The gas supply 5 includes a gas source 51 and a gas line 52. The gas source 51 includes, for example, various processing gas sources, mass flow controllers, and valves (none of which are illustrated). Various processing gases include an adsorption-inhibiting gas, a silicon-containing gas, nitrogen-containing a a gas, modifying gas, and a purge gas, which are used in the method of forming a silicon nitride film according to embodiments to be described later. The various gases are introduced from the gas source 51 into the gas diffusion space 33 via the gas line 52 and the gas introduction hole 36.

The adsorption-inhibiting gas contains a halogen gas and a non-halogen gas. Examples of the halogen gas include fluorine gas (F₂), chlorine gas (Cl₂), and hydrogen fluoride gas (HF). Examples of the non-halogen gas include nitrogen gas (N₂) and a silane coupling agent. Examples of the silicon-containing gas include gases containing halogens, such as chlorine (Cl), bromine (Br), and iodine (I), as well as silicon (Si). Examples of the nitrogen-containing gas include ammonia gas (NH₃) and hydrazine gas (N₂H₄). Examples of the modifying gas include hydrogen gas (H₂). Examples of the purge gas include nitrogen gas (N₂) and argon gas (Ar).

The film forming apparatus is a capacitively coupled plasma apparatus, in which the mounting table 2 functions as a lower electrode and the shower head 3 functions as an upper electrode. The mounting table 2 is grounded via a capacitor (not illustrated). However, the mounting table 2 may be grounded without, for example, a capacitor, or may be grounded via a circuit in which a capacitor and a coil are combined. The shower head 3 is connected to the RF power supply 8.

The RF power supply supplies radio frequency power (hereinafter, also referred to as “RF power”) to the shower head 3. The RF power supply 8 includes an RF power source 81, a matcher 82, and a feeding line 83. The RF power source 81 is a power source that generates RF power. The RF power has a frequency suitable for plasma generation. The frequency of the RF power is, for example, a frequency in the range of 450 KHz in a low frequency band to 2.45 GHz in the microwave band. The RF power source 81 is connected to the main body 31 of the shower head 3 via the matcher 82 and the feeding line 83. The matcher 82 has a circuit configured to match a load impedance with the internal impedance of the RF power source 81. The RF power supply 8 has been described as supplying RF power to the shower head 3 which serves as the upper electrode, but the disclosure is not limited thereto. The RF power may be supplied to the mounting table 2 that serves as the lower electrode.

The controller 9 is, for example, a computer and includes a central processing unit (CPU), a random access memory (RAM), a read only memory (ROM), an auxiliary storage device, and the like. The CPU operates based on a program stored in the ROM or the auxiliary storage device, and controls the operation of the film forming apparatus. The controller 9 may be provided either inside or outside the film forming apparatus. In the case where the controller 9 is provided outside the film forming apparatus, the controller 9 can control the film forming apparatus via a wired or wireless communication mechanism.

### Method of Forming Silicon Nitride Film

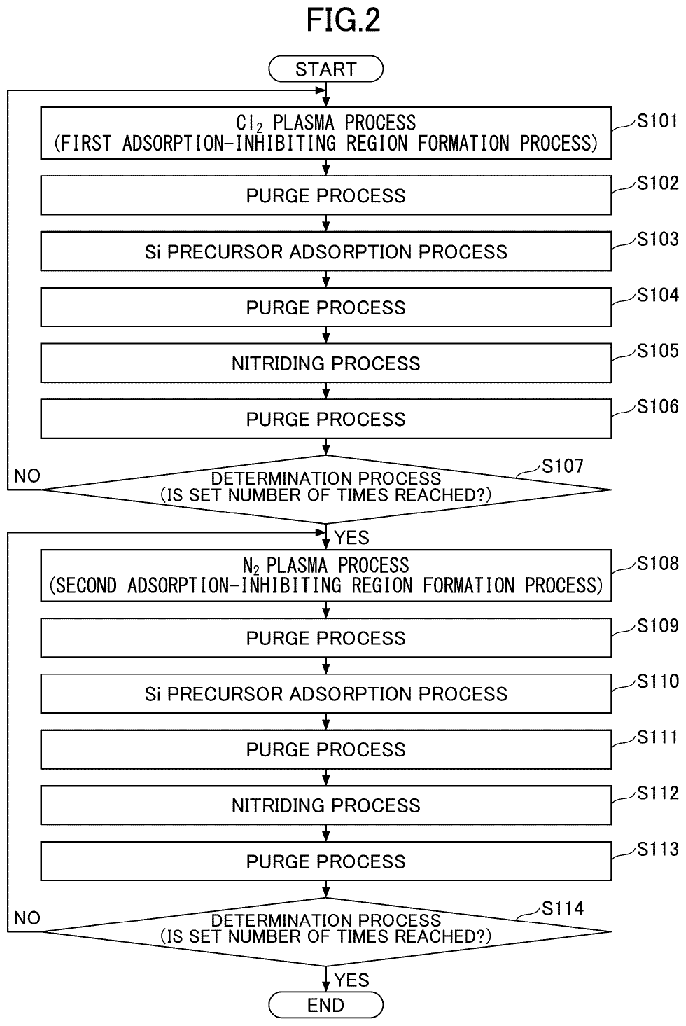

A case where an example of a method of forming a silicon nitride film according to a first embodiment is performed by using the above-described film forming apparatus will be described with reference to FIG. 2. FIG. 2 is a flowchart illustrating an example of a method of forming a silicon nitride film according to the first embodiment. In the present embodiment, a silicon wafer is used as the wafer W, and a trench is formed in the silicon wafer as a recess. The inner portion of the trench and the surface of the wafer W are made of, for example, silicon or an insulating film, and a metal or a metal compound may be partially present therein.

First, the controller 9 carries the wafer W having a trench formed on the surface thereof into the processing container 1. The controller 9 controls the lifting mechanism 24 to open the gate valve 12 in the state in which the mounting table 2 is lowered to the transport position. Subsequently, by a transport arm (not illustrated), the wafer W is carried into the processing container 1 through the loading/unloading port 11 and placed on the mounting table 2 heated to a predetermined temperature (for example, 600° C. or less) by the heater 21. Subsequently, the controller 9 controls the lifting mechanism 24 to raise the mounting table 2 to the processing position, and depressurizes the interior of the processing container 1 to a predetermined degree of vacuum by the exhaust mechanism 42.

Subsequently, a Cl₂ plasma process S101 is performed as a first adsorption-inhibiting region formation process. In the Cl₂ plasma process S101, the wafer W is exposed to a plasma generated from chlorine gas to form an adsorption-inhibiting region in the upper portion of the trench and on the surface of the wafer W. In the present embodiment, the controller 9 supplies chlorine gas from the gas supply 5 into the processing container 1 through the shower head 3, and supplies the RF power to the shower head 3 from the RF power supply 8. As a result, plasma is generated from the chlorine gas in the processing container 1, and active species (reactive species) such as chlorine radicals and chlorine ions are supplied into the trench formed on the surface of the wafer W. The active species are physically adsorbed or chemically adsorbed on the surface. Because the adsorbed chlorine has a function of inhibiting the adsorption of DCS in a Si precursor adsorption process S103, which will be described later, the region where the chlorine has been adsorbed becomes an adsorption-inhibiting region for the DCS. Here, the active species can easily reach the surface of the wafer W and the upper portion in the trench, but not as many reach the inner portion of the trench, that is, the lower portion near the bottom portion. In the trench, many of the active species collide with the side wall before reaching the inner portion of the trench, and are adsorbed or deactivated. Therefore, chlorine is adsorbed at a high density on the surface of the wafer W and the upper portion of the trench, but in the lower portion of the trench, a large amount of unadsorbed portion remains and the density of the adsorbed chlorine is relatively low.

The RF power in the Cl₂ plasma process S101 is preferably smaller than the RF power in a nitriding process S105 to be described later. This is because, in the Cl₂ plasma process S101, it is necessary to relatively limit a dose of active species in order to form an adsorbed chlorine density gradient inside the trench, whereas, in the nitriding process S105, the entire film inside the trench is sufficiently nitrided.

The process conditions in the Cl₂ plasma process S101 are, for example, as follows.
Time: 0.05 seconds to 6 seconds
RF power: 10 W to 500 W
Pressure: 0.1 Torr (13.3 Pa) to 50 Torr (6.7 kPa)

Subsequently, a purge process S102 is performed. In the purge process S102, gas remaining in the processing container 1 after the Cl₂ plasma process S101 is removed. In the present embodiment, the controller 9 supplies argon gas from the gas supply 5 into the processing container 1 through the shower head 3 and evacuates the interior of the processing container 1 by the exhaust 4. As a result, the gas remaining in the processing container 1 is discharged together with the argon gas. The purge process S102 may be omitted.

Subsequently, the Si precursor adsorption process S103 is performed. In the Si precursor adsorption process S103, by supplying DCS to the wafer W, the DCS is adsorbed on a region other than the adsorption-inhibiting region, thereby forming a Si-containing layer. In the present embodiment, the controller 9 supplies the DCS from the gas supply 5 into the processing container 1 via the shower head 3. The DCS is not adsorbed so much in a region where adsorbed chlorine having an adsorption-inhibiting function is present, but is adsorbed more in a region where there are few adsorption-inhibiting groups. Therefore, a large amount of DCS is adsorbed near the bottom of the trench, and a small amount of DCS is adsorbed on the surface of the wafer W and the upper portion of the trench. In other words, the DCS is adsorbed at a high density near the bottom of the trench, and the DCS is adsorbed at a relatively low density in the upper portion of the trench and on the surface of the wafer W.

Subsequently, a purge process S104 is performed. In the purge process S104, the gas remaining in the processing container 1 after the Si precursor adsorption process S103 is removed. In the present embodiment, the controller 9 supplies argon gas from the gas supply 5 into the processing container 1 through the shower head 3 and evacuates the interior of the processing container 1 by the exhaust 4. As a result, the gas remaining in the processing container 1 is discharged together with the argon gas. The purge process S104 may be omitted.

Subsequently, the nitriding process S105 is performed. In the nitriding process S105, the wafer

W is exposed to a plasma generated from the ammonia gas, and the Si-containing layer formed on the surface of the wafer W and in the trench is nitrided to form a silicon nitride film. In the present embodiment, the controller 9 supplies the ammonia gas from the gas supply 5 into the processing container 1 through the shower head 3, and supplies the RF power to the shower head 3 from the RF power supply 8. As a result, in the processing container 1, plasma is generated from the ammonia gas, and active species for nitriding are supplied to the surface of the wafer W and into the trench. The active species react with the Si-containing layer formed in the trench, and a molecular layer of a silicon nitride film is formed as a reaction product. Here, because a large amount of the Si-containing layer is formed near the bottom of the trench, a thick silicon nitride film is formed near the bottom of the trench. Therefore, embedded film formation with a high bottom-up property is possible.

The process conditions in the nitriding process S105 are, for example, as follows.
Time: 1 second to 10 seconds
RF power: 100 W to 3 KW
Pressure: 0.1 Torr (13.3 Pa) to 50 Torr (6.7 kPa)

Subsequently, a purge process S106 is performed. In the purge process S106, the gas remaining in the processing container 1 after the nitriding process S105 is removed. In the present embodiment, the controller 9 supplies argon gas from the gas supply 5 into the processing container 1 through the shower head 3 and evacuates the interior of the processing container 1 by the exhaust 4. As a result, the gas remaining in the processing container 1 is discharged together with the argon gas. The purge process S106 may be omitted.

Subsequently, a determination process S107 is performed. In the determination process S107, the controller 9 determines whether the number of repetitions of the processes from the Cl₂ plasma process S101 to the purge process S106 reaches a set number of times. The set number of times is determined depending on, for example, the number of repetitions until a silicon nitride film is deposited in the recess from the bottom side and the aspect ratio of the recess becomes smaller than a predetermined value. When it is determined in the determination process S107 that the number of repetitions reaches the set number of times, processing is terminated. Whereas, when it is determined in the determination process S107 that the number of repetitions has not reached the set number of times, the operation returns to the Cl₂ plasma process S101.

In this manner, the processes from the Cl₂ plasma process S101 to the purge process S106 are repeated, and a silicon nitride film is deposited from the bottom side in a state where the opening of the trench is not blocked. Then, while forming a V-shaped cross section, a silicon nitride film can be formed with a high bottom-up property that does not block the opening. As a result, a high-quality silicon nitride film can be embedded in the trench without generating a void.

Subsequently, a N₂ plasma process S108 is performed as a second adsorption-inhibiting region formation process. In the N₂ plasma process S108, the wafer W is exposed to a plasma generated from nitrogen gas to form an adsorption-inhibiting region in the upper portion of the trench and on the surface of the wafer W. In the present embodiment, the controller 9 supplies nitrogen gas from the gas supply 5 into the processing container 1 through the shower head 3, and supplies the RF power to the shower head 3 from the RF power supply 8. As a result, plasma is generated from the nitrogen gas within the processing container 1, and active species, such as nitrogen radicals and nitrogen ions, are supplied into the trench formed on the surface of the wafer W. The active species are physically adsorbed or chemically adsorbed to sites where chlorine is not adsorbed in the Cl₂ plasma process S101. Because the adsorbed nitrogen has a function of inhibiting the adsorption of DCS in the Si precursor adsorption process S110, which will be described later, the region where the nitrogen has been adsorbed becomes an adsorption-inhibiting region for the DCS. Here, the active species can easily reach the surface of the wafer W or the upper portion in the trench, but not as many reach the inner portion of the trench, that is, the lower portion near the bottom portion. In the trench, many of the active species collide with the side wall before reaching the inner portion of the trench, and are adsorbed or deactivated. Therefore, nitrogen is adsorbed at a high density on the surface of the wafer W and the upper portion of the trench, but in the lower portion of the trench, a large amount of unadsorbed portion remains and the density of the adsorbed nitrogen is relatively low.

The RF power in the N₂ plasma process S108 is preferably smaller than the RF power in the nitriding process S112 to be described later. This is because, in the N₂ plasma process S108, it is necessary to relatively limit a dose of active species in order to form an adsorbed nitrogen density gradient inside the trench, whereas in the nitriding process S112, it is necessary that the entire film inside the trench is sufficiently nitrided.

The process conditions in the N₂ plasma process S108 are, for example, as follows.
Time: 0.1 seconds to 6 seconds.
RF power: 10 W to 1 kW
Pressure: 0.1 Torr (13.3 Pa) to 50 Torr (6.7 kPa)

Subsequently, a purge process S109 is performed. In the purge process S109, gas remaining in the processing container 1 after the N₂ plasma process S108 is removed. In the present embodiment, the controller 9 supplies argon gas from the gas supply 5 into the processing container 1 through the shower head 3 and evacuates the interior of the processing container 1 by the exhaust 4. As a result, the gas remaining in the processing container 1 is discharged together with the argon gas. The purge process S109 may be omitted.

Subsequently, the Si precursor adsorption process S110 is performed. In the Si precursor adsorption process S110, by supplying DCS to the wafer W, the DCS is adsorbed on a region other than the adsorption-inhibiting region, thereby forming a Si-containing layer. In the present embodiment, the controller 9 supplies the DCS from the gas supply 5 into the processing container 1 via the shower head 3. The DCS is not adsorbed so much in a region where adsorbed nitrogen having an adsorption-inhibition function is present, but is adsorbed more in a region where there are few adsorption-inhibiting groups. Therefore, a large amount of DCS is adsorbed near the bottom of the trench, and a small amount of DCS is adsorbed on the surface of the wafer W and the upper portion of the trench. In other words, the DCS is adsorbed at a high density near the bottom of the trench, and the DCS is adsorbed at a relatively low density in the upper portion of the trench and on the surface of the wafer W.

Subsequently, a purge process S111, a nitriding process S112, and a purge process S113 are performed in this order. The purge process S111, the nitriding process S112, and the purge process S113 may be the same as the purge process S104, the nitriding process S105, and the purge process S106. In the purge process S111, the gas remaining in the processing container 1 after the Si precursor adsorption process S110 is removed. In the present embodiment, the controller 9 supplies argon gas from the gas supply 5 into the processing container 1 through the shower head 3 and evacuates the interior of the processing container 1 by the exhaust 4. As a result, the gas remaining in the processing container 1 is discharged together with the argon gas. The purge process S111 may be omitted.

Subsequently, the nitriding process S112 is performed. In the nitriding process S112, the wafer W is exposed to a plasma generated from the ammonia gas, and the Si-containing layer formed on the surface of the wafer W and in the trench is nitrided to form a silicon nitride film. In the present embodiment, the controller 9 supplies the ammonia gas from the gas supply 5 into the processing container 1 through the shower head 3, and supplies the RF power to the shower head 3 from the RF power supply 8. As a result, in the processing container 1, plasma is generated from the ammonia gas, and active species for nitriding are supplied to the surface of the wafer W and into the trench. The active species react with the Si-containing layer formed in the trench, and a molecular layer of a silicon nitride film is formed as a reaction product. Here, because a large amount of the Si-containing layer is formed near the bottom of the trench, a thick silicon nitride film is formed near the bottom of the trench. Therefore, embedded film formation with a high bottom-up property is possible.

The process conditions in the nitriding process S112 are, for example, as follows.
Time: 1 second to 10 seconds
RF power: 100 W to 3 KW
Pressure: 0.1 Torr (13.3 Pa) to 50 Torr (6.7 kPa)

Subsequently, a purge process S113 is performed. In the purge process S113, the gas remaining in the processing container 1 after the nitriding process S112 is removed. In the present embodiment, the controller 9 supplies argon gas from the gas supply 5 into the processing container 1 through the shower head 3 and evacuates the interior of the processing container 1 by the exhaust 4. As a result, the gas remaining in the processing container 1 is discharged together with the argon gas. The purge process S113 may be omitted.

Subsequently, a determination process S114 is performed. In the determination process S114, the controller 9 determines whether the number of repetitions of the processes from the N₂ plasma process S108 to the purge process S113 reaches a set number of times. The set number is determined depending on, for example, the thickness of a silicon nitride film to be formed. When it is determined in the determination process S114 that the number of repetitions reaches the set number of times, processing is terminated. Whereas, when it is determined in the determination process S114 that the number of repetitions has not reached the set number of times, the operation returns to the N₂ plasma process S108.

In this manner, the processes from the N₂ plasma process S108 to the purge process S113 are repeated, and a silicon nitride film is deposited from the bottom side in a state where the opening of the trench is not blocked. Then, while forming a V-shaped cross section, a silicon nitride film can be formed with a high bottom-up property that does not block the opening. As a result, a high-quality silicon nitride film can be embedded in the trench without generating a void.

That is, in the method of forming a silicon nitride film according to the first embodiment, as the adsorption-inhibiting region formation process, the Cl₂ plasma process S101 is performed in the early stage of the film forming process at which the aspect ratio of the recess is large, and the N₂ plasma process S108 is performed in the later stage of the film forming process at which the aspect ratio of the recess is small.

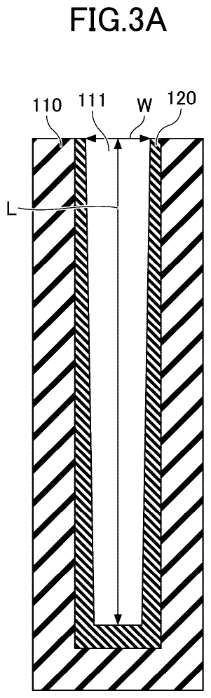

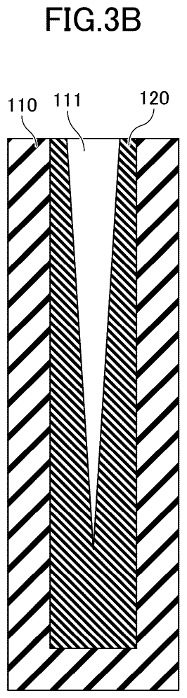

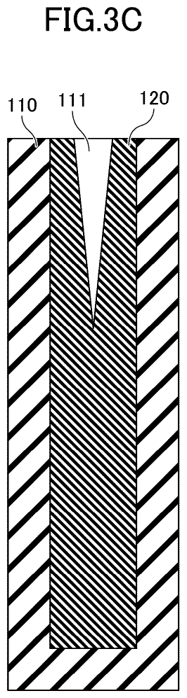

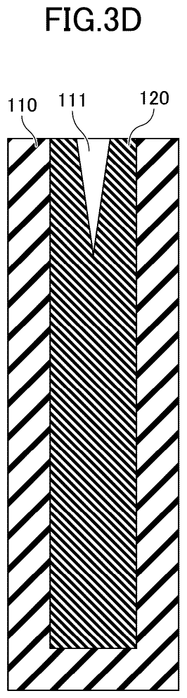

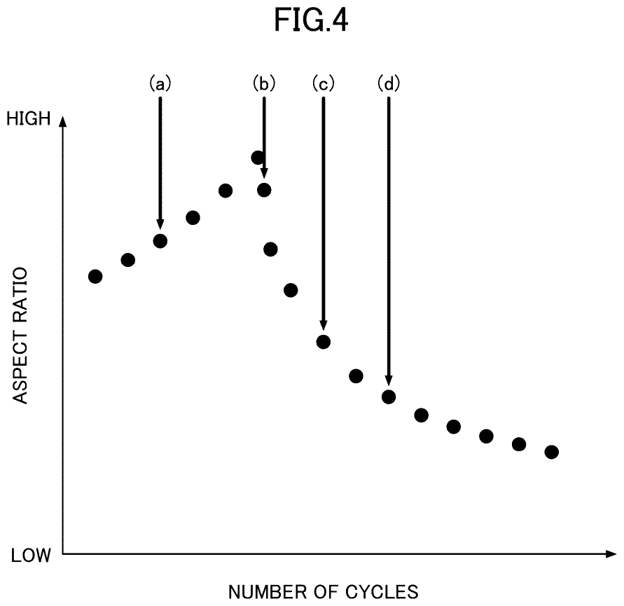

Next, changes in the aspect ratio of the recess when the silicon nitride film is embedded in the recess formed in the wafer W will be described with reference to FIGS. 3A to 4. FIGS. 3A to 3D are cross-sectional schematic diagrams illustrating changes in the aspect ratio of a recess 111 when a silicon nitride film 120 is embedded in the recess 111. FIG. 4 is an example of a graph illustrating a relationship between a number of cycles of the film forming process of the silicon nitride film 120 and the aspect ratio of the recess 111. In FIG. 4, positions corresponding to FIGS. 3A to 3D are indicated by (a) to (d), respectively.

As illustrated in FIG. 3A, the recess 111 such as a hole and a trench is formed in the substrate 110. By the ALD cycle (see S103 to S106 and S110 to S113), the silicon nitride film 120 is formed from the side wall and the bottom of the recess 111. Here, by forming the adsorption-inhibiting region on the upper portion of the side wall of the recess 111 and the surface of the substrate 110, the silicon nitride film 120 formed on the side wall of the recess 111 is formed thicker on the bottom side than on the upper portion side.

When the film formation of the silicon nitride film 120 is continued, as illustrated in FIG. 3B, each part of the silicon nitride film 120 formed from the left and right side walls of the recess 111 comes into contact on the bottom side of the recess 111. As a result, the silicon nitride film 120 is formed to have a V-shaped cross section. When the film formation of the silicon nitride film 120 is further continued, as illustrated in FIGS. 3C and 3D, while forming a V-shaped cross section of the silicon nitride film 120, a silicon nitride film can be formed with a high bottom-up property that does not block the opening.

Here, the opening width of the recess 111 is W, the depth of the recess 111 is L, and the aspect ratio of the recess 111 is (L/W).

In the initial stage of the film formation of the silicon nitride film 120, a film formation speed (GPC) at the side wall and the bottom of the recess 111 is determined by the adsorption amount of the DCS and the nitridation reaction amount by the plasma generated from the ammonia gas. At this time, the ratio of the film formation amount at the bottom of the recess 111 with respect to the depth of the recess 111 before film formation starts is relatively smaller than the ratio of the film formation amount at the upper portion of the side wall of the recess 111 with respect to the opening width of the recess 111 before film formation starts. Therefore, as illustrated in FIG. 4, the aspect ratio gradually increases in the initial stage of the film formation of the silicon nitride film 120.

When each part of the silicon nitride film 120 formed from the left and right side walls of the recess 111 comes into contact on the bottom side of the recess 111 (see FIG. 3B), the silicon nitride film 120 is formed to have a V-shaped cross section. At this time, the film formation speed at the bottom of the V-shaped cross section changes as determined by a change in the tilt angle depending on the film formation speed distribution of the side wall. Because the film formation speed (GPC) of the lower portion of the recess 111 is higher than that of the upper portion, the tilt angle of the side wall becomes smaller as the film formation proceeds, and thus an amount of decrease in a depth L of the recess 111 increases compared to the initial stage of the film formation. That is, as illustrated in FIG. 4, after the side walls of the silicon nitride film 120 contact, the rise of the bottom of the recess 111 increases, and the aspect ratio rapidly decreases.

In this manner, as illustrated in FIGS. 3A to 4, when the silicon nitride film 120 is embedded in the recess 111, the aspect ratio of the recess 111 changes.

Next, the concentration distribution of the adsorption-inhibiting gas in the recess will be described with reference to FIG. 5. FIG. 5 is an example of a graph for explaining the concentration distribution of the adsorption-inhibiting gas in the recess. The horizontal axis represents the normalized height position with the bottom (BTM) of the recess 111 set to 0 and the opening (the upper surface (TOP) of the substrate 110) of the recess 111 set to 1. The vertical axis represents the normalized gas concentration with the gas concentration in the opening (the upper surface of the substrate 110) of the recess 111 set to 1. The plots AR2, AR4, and AR8 represent the cases where the aspect ratio is 2, 4, and 8, respectively.

As illustrated in FIG. 5, the larger the aspect ratio, the greater the difference in gas concentration between the opening of the recess 111 and the bottom of the recess 111. The smaller the aspect ratio, the smaller the difference in gas concentration between the opening of the recess 111 and the bottom of the recess 111.

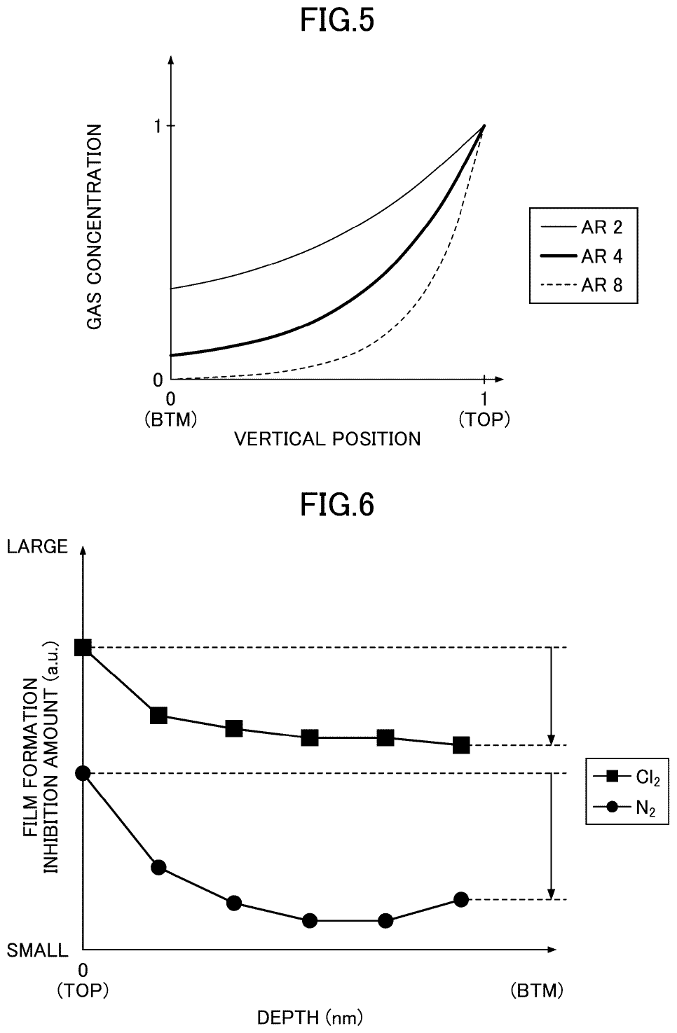

Next, the adsorption-inhibiting effect of the adsorption-inhibiting gas will be described with reference to FIG. 6. FIG. 6 is an example of a graph for explaining the inhibition effect by the adsorption-inhibiting gas. The horizontal axis indicates the depth (nm) of the recess 111. That is, the left side of the horizontal axis corresponds to the opening (TOP) side of the recess 111, and the right side of the horizontal axis corresponds to the bottom (BTM) side of the recess 111. The vertical axis indicates the film formation inhibition amount (the difference between the film formation speed when the adsorption-inhibiting gas is not used and the film formation speed when the adsorption-inhibiting gas is used). The result when Cl₂ gas is used as the adsorption-inhibiting gas is indicated by square symbols, and the result when N₂ gas is used as the adsorption-inhibiting gas is indicated by circle symbols.

As illustrated in FIG. 5, when Cl₂ gas is used, the film formation inhibition amount is higher than when N₂ gas is used. That is, Cl₂ gas has a higher adsorption-inhibiting effect than N₂ gas.

When Cl₂ gas is used, the difference (indicated by an arrow in FIG. 5) between the opening (TOP) of the recess 111 and the bottom (BTM) of the recess 111 is smaller than when N₂ gas is used. That is, with respect to Cl₂ gas, the adsorption-inhibiting effect changes little in the depth direction of the recess, and with respect to N₂ gas, the adsorption-inhibiting effect changes greatly in the depth direction of the recess.

Thus, Cl₂ gas and N₂ gas used as the adsorption-inhibiting gas have different characteristics.

In the method of forming a silicon nitride film according to the first embodiment, in the early stage of the film forming process, the aspect ratio of the recess 111 is high as illustrated in FIGS. 3A to 4, and the concentration distribution of the active species of the adsorption-inhibiting gas tends to differ in the depth direction of the recess 111 as illustrated in FIG. 5. For this reason, Cl₂ gas having a high adsorption-inhibiting effect is used (see S101). As a result, chlorine is adsorbed at a high density on the surface of the wafer W and on the upper portion of the recess 111, whereas a large amount of unadsorbed portion remains in the lower portion of the recess 111, and the density of the adsorbed chlorine is low. As a result, while forming a V-shaped cross section, a silicon nitride film can be formed with a high bottom-up property that does not block the opening of the recess 111.

In contrast, in the later stage of the film forming process, the aspect ratio of the recess 111 is low as illustrated in FIGS. 3A to 4, and the concentration distribution of the active species of the adsorption-inhibiting gas tends to be relatively uniform in the depth direction of the recess 111, as illustrated in FIG. 5. For this reason, N₂ gas that has a large variation in the adsorption-inhibiting effect in the depth direction of the recess 111 is used (see S108). As a result, while forming a V-shaped cross section, a silicon nitride film can be formed with a high bottom-up property that does not block the opening of the recess 111.

Further, as illustrated in FIG. 6, because the adsorption-inhibiting effect of the N₂ gas is lower than that of the Cl₂ gas, the film formation speed can be improved. That is, productivity of the substrate processing can be improved.

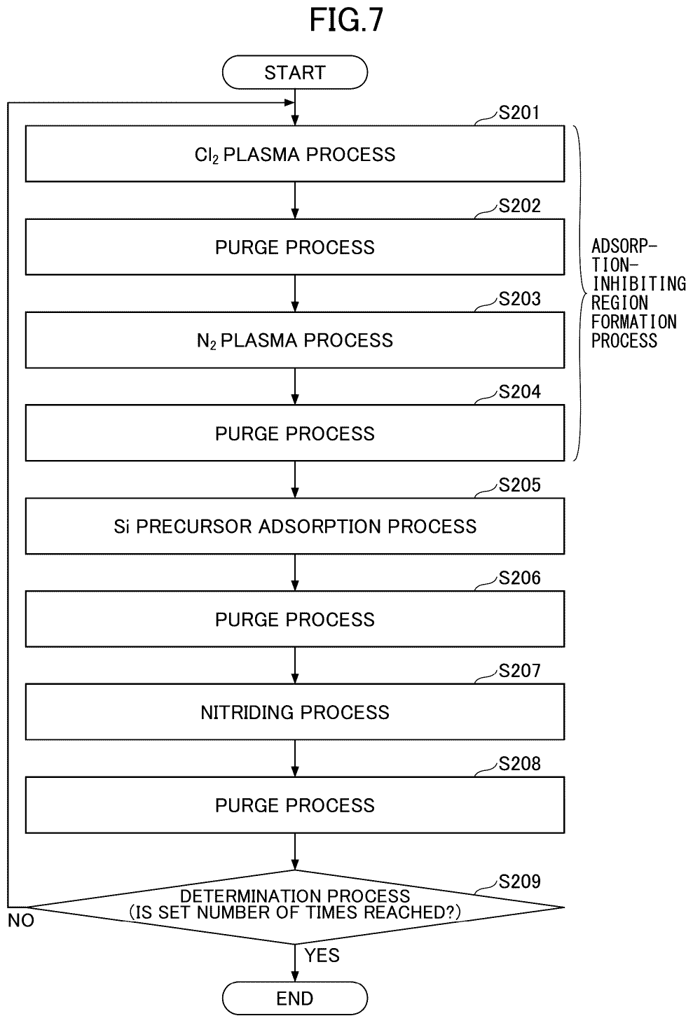

Next, a case where an example of a method of forming a silicon nitride film according to a second embodiment is performed by using the above-described film forming apparatus will be described with reference to FIG. 7. FIG. 7 is a flowchart illustrating an example of a method of forming a silicon nitride film according to the second embodiment. Here, in the method of forming illustrated in FIG. 7, the processing of the adsorption-inhibiting region formation process is different from that of the method illustrated in FIG. 2. In other respects, the method is the same as the method illustrated in FIG. 2. In the following, points different from the method illustrated in FIG. 2 will be mainly described.

First, the controller 9 carries the wafer W having a trench formed on the surface thereof into the processing container 1. The method of carrying the wafer W into the processing container 1 may be the same as the method illustrated in FIG. 2 described above.

In the method of forming the silicon nitride film according to the second embodiment, the adsorption-inhibiting region formation process includes a Cl₂ plasma process S201, a purge process S202, a N₂ plasma process S203, and a purge process S204.

First, the Cl₂ plasma process S201 is performed as a process of forming an adsorption-inhibiting region. In the Cl₂ plasma process S201, the wafer W is exposed to a plasma generated from chlorine gas to form an adsorption-inhibiting region in the upper portion of the trench and on the surface of the wafer W. In the present embodiment, the controller 9 supplies chlorine gas from the gas supply 5 into the processing container 1 through the shower head 3, and supplies the RF power to the shower head 3 from the RF power supply 8. As a result, plasma is generated from the chlorine gas in the processing container 1, and active species (reactive species) such as chlorine radicals and chlorine ions are supplied into the trench formed on the surface of the wafer W. The active species are physically adsorbed 10 or chemically adsorbed on the surface. Because the adsorbed chlorine has a function of inhibiting the adsorption of DCS in a Si precursor adsorption process S205, which will be described later, the region where the chlorine has been adsorbed becomes an adsorption-inhibiting region for the DCS. Here, the active species can easily reach the surface of the wafer W and the upper portion in the trench, but not as many reach the inner portion of the trench, that is, the lower portion near the bottom portion. In the trench, many of the active species collide with the side wall before reaching the inner portion of the trench, and are adsorbed or deactivated. Therefore, chlorine is adsorbed at a high density on the surface of the wafer W and the upper portion of the trench, but in the lower portion of the trench, a large amount of unadsorbed portion remains and the density of the adsorbed chlorine is relatively low.

The RF power in the Cl₂ plasma process S201 is preferably smaller than the RF power in a nitriding process S207 to be described later. This is because, in the Cl; plasma process S201, it is necessary to relatively limit a dose of active species in order to form an adsorbed chlorine density gradient inside the trench, whereas, in the nitriding process S207, the entire film inside the trench is sufficiently nitrided.

The process conditions in the Cl₂ plasma process S201 are, for example, as follows.
Time: 0.05 seconds to 6 seconds
RF power: 10 W to 500 W
Pressure: 0.1 Torr (13.3 Pa) to 50 Torr (6.7 kPa)

Subsequently, the purge process S202 is performed. In the purge process S202, gas remaining in the processing container 1 after the Cl₂ plasma process S201 is removed. In the present embodiment, the controller 9 supplies argon gas from the gas supply 5 into the processing container 1 through the shower head 3 and evacuates the interior of the processing container 1 by the exhaust 4. As a result, the gas remaining in the processing container 1 is discharged together with the argon gas. The purge process S202 may be omitted.

Subsequently, the N₂ plasma process S203 is performed as a process of forming an adsorption-inhibiting region. In the N₂ plasma process S203, the wafer W is exposed to a plasma generated from nitrogen gas to form an adsorption-inhibiting region in the upper portion of the trench and on the surface of the wafer W. In the present embodiment, the controller 9 supplies nitrogen gas from the gas supply 5 into the processing container 1 through the shower head 3, and supplies the RF power to the shower head 3 from the RF power supply 8. As a result, plasma is generated from the nitrogen gas within the processing container 1, and active species, such as nitrogen radicals and nitrogen ions, are supplied into the trench formed on the surface of the wafer W. The active species are physically adsorbed or chemically adsorbed to sites where chlorine is not adsorbed in the Cl₂ plasma process S201. Because the adsorbed nitrogen has a function of inhibiting the adsorption of DCS in the Si precursor adsorption process S205, which will be described later, the region where nitrogen has been adsorbed becomes an adsorption-inhibiting region for the DCS. Here, the active species can easily reach the surface of the wafer W or the upper portion of the trench, but not as many reach the inner portion of the trench, that is, the lower portion near the bottom portion. In the trench, many of the active species collide with the side wall before reaching the inner portion of the trench, and are adsorbed or deactivated. Therefore, nitrogen is adsorbed at a high density on the surface of the wafer w and the upper portion of the trench, but in the lower portion of the trench, a large amount of unadsorbed portion remains and the density of the adsorbed nitrogen is relatively low.

The RF power in the N₂ plasma process S203 is preferably smaller than the RF power in the nitriding process S207 to be described later. This is because, in the N₂ plasma process S203, it is necessary to relatively limit a dose of active species in order to form an adsorbed nitrogen density gradient inside the trench, whereas in the nitriding process S207, it is necessary that the entire film inside the trench is sufficiently nitrided.

The process conditions in the N₂ plasma process S203 are, for example, as follows.
Time: 0.1 seconds to 6 seconds
RF power: 10 W to 1 kw
Pressure: 0.1 Torr (13.3 Pa) to 50 Torr (6.7 kPa)

Subsequently, the purge process S204 is performed. In the purge process S204, gas remaining in the processing container 1 after the N₂ plasma process S203 is removed. In the present embodiment, the controller 9 supplies argon gas from the gas supply 5 into the processing container 1 through the shower head 3 and evacuates the interior of the processing container 1 by the exhaust 4. As a result, the gas remaining in the processing container 1 is discharged together with the argon gas. The purge process S204 may be omitted.

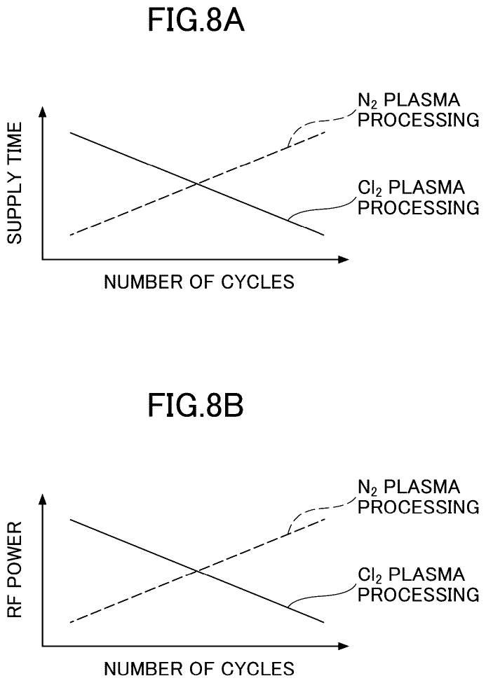

Here, the adjustment parameters in the adsorption-inhibiting region formation process will be described with reference to FIGS. 8A and 8B. FIGS. 8A and 8B are examples of graphs illustrating changes in the adjustment parameters as the number of cycles increases.

A case where a supply time (a plasma processing time) of the adsorption-inhibiting gas is changed as the adjustment parameter will be described with reference to FIG. 8A. FIG. 8A is an example of a graph illustrating a change in the gas supply time as the number of cycles increases. The horizontal axis indicates the number of cycles (the count of repetition of S209), and the vertical axis indicates the supply time of each gas.

In the early stage of the film forming process, the supply time of Cl₂ gas in step S201 is increased and the supply time of N₂ gas in step S203 is decreased. Thus, an adsorption-inhibiting region is formed in a state where the adsorption-inhibiting effect by the Cl₂ gas is relatively high.

In the later stage of the film forming process, the supply time of the Cl₂ gas in step S201 is decreased and the supply time of N₂ gas in step S203 is increased. Thus, an adsorption-inhibiting region is formed in a state where the adsorption-inhibiting effect by the N₂ gas is relatively high.

Here, the supply time of the Cl₂ gas may be decreased as the number of cycles increases, regardless of the supply time of the N₂ gas. For example, the supply time of the Cl₂ gas may be longer than or equal to the supply time of the N₂ gas in the early stage of the film forming process, and the supply time of the Cl₂ gas may be shorter than or equal to the supply time of the N₂ gas in the later stage of the film forming process. For example, in the early stage of the film forming process, the supply time of the Cl₂ gas may be shorter than or equal to the supply time of the N₂ gas, and in the later stage of the film forming process, the supply time of the Cl₂ gas may be shorter than that in the early stage of the film forming process. The supply time of the N₂ gas may be increased as the number of cycles increases, or may be constant. When the supply time of the N₂ gas is constant, the adsorption-inhibiting effect can be controlled by controlling the supply time of the Cl₂ gas.

A case where the RF power of the adsorption-inhibiting gas in the plasma processing (S201 and S203) is changed as the adjustment parameter will be described with reference to FIG. 8B. FIG. 8B is an example of a graph illustrating a change in the RF power as the number of cycles increases. The horizontal axis indicates the number of cycles (the count of repetition of S209), and the vertical axis indicates the RF power in the plasma processing of each gas.

In the early stage of the film forming process, the RF power in the Cl₂ plasma process in step S201 is increased and the RF power in the N₂ plasma process in step S203 is decreased. Thus, an adsorption-inhibiting region is formed in a state where the adsorption-inhibiting effect by the Cl₂ gas is relatively high.

In the later stage of the film forming process, the RF power in the Cl₂ plasma process in step S201 is decreased and the RF power in the N₂ plasma process in step S203 is increased. Thus, an adsorption-inhibiting region is formed in a state where the adsorption-inhibiting effect by the N₂ gas is relatively high.

Here, the RF power of the Cl₂ gas may be decreased as the number of cycles increases, regardless of the RF power of the N₂ gas. For example, the RF power of the Cl₂ gas may be greater than or equal to the RF power of the N₂ gas in the early stage of the film forming process, and the RF power of the Cl₂ gas may be less than the RF power of the N₂ gas in the later stage of the film forming process. For example, the RF power of the Cl₂ gas may be less than or equal to the RF power of the N₂ gas in the early stage of the film forming process, and the RF power of the Cl₂ gas in the later stage of the film forming process may be less than that in the early stage of the film forming process. The RF power of the N₂ gas may be increased as the number of cycles increases, or may be constant. When the RF power of the N₂ gas is constant, the adsorption-inhibiting effect can be controlled by controlling the RF power of the Cl₂ gas.

FIGS. 8A and 8B illustrate that the adjustment parameters are changed continuously as the number of cycles increases, but the disclosure is not limited thereto. The adjustment parameter may be changed stepwise in the early stage and the later stage of the film forming process, or the adjustment parameter may be changed in multiple stages.

The adjustment parameter in the adsorption-inhibiting region formation process is not limited to these parameters. For example, the above-described gas supply time may be combined with the magnitude of the RF power, and the impedance, bias voltage, and the like may be changed.

Subsequently, the Si precursor adsorption process S205, a purge process S206, the nitriding process S207, and a purge process S208 are performed in this order. The Si precursor adsorption process S205, the purge process S206, the nitriding process S207, and the purge process S208 may be the same as the Si precursor adsorption process S103, the purge process S104, the nitriding process S105, and the purge process S106.

Subsequently, a determination process S209 is performed. In the determination process S209, the controller 9 determines whether the number of repetitions of the processes from the Cl₂ plasma process S201 to the purge process S208 reaches a set number of times. The set number of times is determined depending on, for example, the thickness of a silicon nitride film to be formed. When it is determined in the determination process S209 that the number of repetitions reaches the set number of times, processing is terminated. Whereas, when it is determined in the determination process S209 that the number of repetitions has not reached the set number of times, the operation returns to the Cl₂ plasma process S201.

In this manner, the processes from the Cl₂ plasma process S201 to the purge process S208 are repeated, and a silicon nitride film is deposited from the bottom side in a state where the opening of the trench is not blocked. Then, while forming a V-shaped cross section, a silicon nitride film can be formed with a high bottom-up property that does not block the opening. As a result, a high-quality silicon nitride film can be embedded in the trench without generating a void.

In the method of forming a silicon nitride film according to the second embodiment, in the early stage of the film forming process, the aspect ratio of the recess is high, and the concentration distribution of the active species of the adsorption-inhibiting gas tends to differ in the depth direction of the recess. For this reason, the adsorption-inhibiting effect of the Cl₂ gas is set to be relatively high. As a result, chlorine is adsorbed at a high density on the surface of the wafer W and on the upper portion of the recess, whereas a large amount of unadsorbed portion remains in the lower portion of the recess, and the density of the adsorbed chlorine is low. As a result, while forming a V-shaped cross section, a silicon nitride film can be formed with a high bottom-up property that does not block the opening of the recess 111.

In contrast, in the later stage of the film forming process, the aspect ratio of the recess is low, and the concentration distribution of the active species of the adsorption-inhibiting gas tends to be relatively uniform in the depth direction of the recess. For this reason, the adsorption-inhibiting effect of the N₂ gas that has a large variation in the adsorption-inhibiting effect in the depth direction of the recess, is set to be relatively high. As a result, while forming a V-shaped cross section, a silicon nitride film can be formed with a high bottom-up property that does not block the opening of the recess.

Because the adsorption-inhibiting effect of the N₂ gas is lower than that of the Cl₂ gas, the film formation speed can be improved. That is, productivity of the substrate processing can be improved.

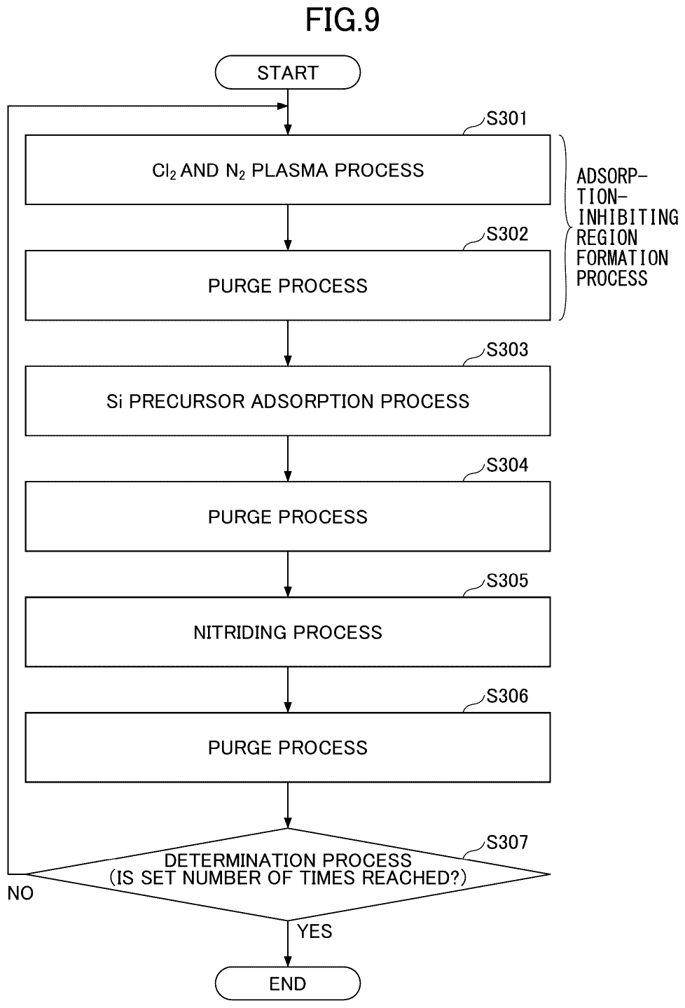

Next, a case where an example of a method of forming a silicon nitride film according to a third embodiment is performed by using the above-described apparatus will be described with film forming reference to FIG. 9. FIG. 9 is a flowchart illustrating an example of a method of forming a silicon nitride film according to the third embodiment. Here, in the method of forming illustrated in FIG. 9, the processing of the adsorption-inhibiting region formation process is different from that of the method illustrated in FIG. 7. In other respects, the method is the same as the method illustrated in FIG. 7. In the following, points different from the method illustrated in FIG. 7 will be mainly described.

First, the controller 9 carries the wafer W having a trench formed on the surface thereof into the processing container 1. The method of carrying the wafer W into the processing container 1 may be the same as the method illustrated in FIG. 7 described above.

In the method of forming the silicon nitride film according to the third embodiment, the adsorption-inhibiting region formation process includes a Cl₂/N₂ plasma process S301 and a purge process S302.

First, the Cl₂/N₂ plasma process S301 is performed as a process of forming an adsorption-inhibiting region. In the Cl₂/N₂ plasma process S301, the wafer W is exposed to a plasma generated from chlorine gas and nitrogen gas to form an adsorption-inhibiting region in the upper portion of the trench and on the surface of the wafer W. In the present embodiment, the controller 9 simultaneously supplies chlorine gas and nitrogen gas from the gas supply 5 into the processing container 1 through the shower head 3, and supplies the RF power to the shower head 3 from the RF power supply 8. As a result, plasma is generated from the chlorine gas and the nitrogen gas in the processing container 1, and active species are supplied into the trench formed on the surface of the wafer W. The active species are physically adsorbed or chemically adsorbed on the surface. Because the adsorbed chlorine has a function of inhibiting the adsorption of DCS in a Si precursor adsorption process S303, which will be described later, the region where the chlorine has been adsorbed becomes an adsorption-inhibiting region for the DCS. Similarly to chlorine, nitrogen is also physically adsorbed or chemically adsorbed on the surface. Because the adsorbed nitrogen has a function of inhibiting the adsorption of DCS in the Si precursor adsorption process S303, which will be described later, the region where the nitrogen has been adsorbed becomes an adsorption-inhibiting region for the DCS. Here, the active species can easily reach the surface of the wafer W and the upper portion in the trench, but not as many reach the inner portion of the trench, that is, the lower portion near the bottom portion. In the trench, many of the active species collide with the side wall before reaching the inner portion of the trench, and are adsorbed or deactivated. Therefore, chlorine and nitrogen are adsorbed at a high density on the surface of the wafer W and the upper portion of the trench, but in the lower portion of the trench, a large amount of unadsorbed portion remains and the densities of the adsorbed chlorine and adsorbed nitrogen are relatively low.

The RF power in the Cl₂/N₂ plasma process S301 is preferably smaller than the RF power in a nitriding process S305. This is because, in the Cl₂/N₂ plasma process S301, an adsorbed density gradient of chlorine and nitrogen inside the trench is formed, whereas, in the nitriding process S305, the entire film inside the trench is sufficiently nitrided.

The process conditions in the Cl₂/N₂ plasma process S301 may be the same as those in, for example, the Cl₂ plasma process S201 or the N₂ plasma process S203.

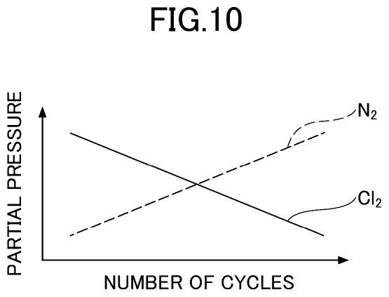

Here, the adjustment parameters in the adsorption-inhibiting region formation process will be described with reference to FIG. 10. FIG. 10 is an example of a graph illustrating a change in the adjustment parameter as the number of cycles increases. Here, a case where a partial pressure of the adsorption-inhibiting gas is changed as the adjustment parameter will be described. The horizontal axis indicates the number of cycles (the count of repetition of S307), and the vertical axis indicates the partial pressure of each gas.

In the early stage of the film forming process, the partial pressure of the Cl₂ gas is set to be high and the partial pressure of the N₂ gas is set to be low in step S301. Thus, an adsorption-inhibiting region is formed in a state where the adsorption-inhibiting effect by the Cl₂ gas is relatively high.

In contrast, in the later stage of the film forming process, the partial pressure of the Cl₂ gas is set to be low and the partial pressure of the N₂ gas is set to be high in step S301. Thus, an adsorption-inhibiting region is formed in a state where the adsorption-inhibiting effect by the N₂ gas is relatively high.

FIG. 10 illustrates that the adjustment parameter is changed continuously as the number of cycles increases, but the disclosure is not limited thereto. The adjustment parameter may be changed stepwise in the early stage and the later stage of the film forming process, or the adjustment parameter may be changed in multiple stages.

The partial pressure of the Cl₂ gas may be decreased as the number of cycles increases, regardless of the partial pressure of the N₂ gas. For example, the partial pressure of the Cl₂ gas may be higher than or equal to the partial pressure of the N₂ gas in the early stage of the film forming process, and the partial pressure of the Cl₂ gas may be lower than the partial pressure of the N₂ gas in the later stage of the film forming process. For example, the partial pressure of the Cl₂ gas may be lower than or equal to the partial pressure of the N₂ gas in the early stage of the film forming process, and the partial pressure of the Cl₂ gas may be lower than that in the early stage of the film forming process in the later stage of the film forming process. The partial pressure of the N₂ gas may be increased as the number of cycles increases, or may be constant. When the partial pressure of the N₂ gas is constant, the adsorption-inhibiting effect can be controlled by controlling the partial pressure of the Cl₂ gas.

The adjustment parameter in the adsorption-inhibiting region formation process is not limited to this parameter. For example, the RF power in the plasma process in step S301 may be changed. For example, the RF power is set to be low in the early stage of the film forming process. As a result, the Cl₂ gas that is more easily dissociated than the N₂ gas is dissociated, and the adsorption-inhibiting region is formed in a state where the adsorption-inhibiting effect by the Cl₂ gas is relatively high. In the later stage of the film forming process, the RF power is set to be higher than that in the early stage. As a result, the N₂ gas is also dissociated, and the adsorption-inhibiting region is formed in a state where the adsorption-inhibiting effect by the N₂ gas is relatively high.

Subsequently, the purge process S302, the Si precursor adsorption process S303, the purge process S304, the nitriding process S305, the purge process S306, and the determination process S307 are performed in this order. The purge process S302, the Si precursor adsorption process S303, the purge process S304, the nitriding process S305, the purge process S306, and the determination process S307 may be the same the purge process S204, the Si precursor adsorption process S205, the purge process S206, the nitriding process S207, the purge process S208, and the determination process S209 illustrated in FIG. 7.

In this manner, the processes from the Cl₂/N₂ plasma process S301 to the purge process S306 are repeated, and a silicon nitride film is deposited from the bottom side in a state where the opening of the trench is not blocked. Then, while forming a V-shaped cross section, a silicon nitride film can be formed with a high bottom-up property that does not block the opening. As a result, a high-quality silicon nitride film can be embedded in the trench without generating a void.

In method of forming a silicon nitride film according to the third embodiment, in the early stage of the film forming process, the aspect ratio of the recess is high, and the concentration distribution of the active species of the adsorption-inhibiting gas tends to differ in the depth direction of the recess. For this reason, the adsorption-inhibiting effect of the Cl₂ gas is set to be relatively high. As a result, chlorine is adsorbed at a high density on the surface of the wafer W and on the upper portion of the recess, whereas a large amount of unadsorbed portion remains in the lower portion of the recess, and the density of the adsorbed chlorine is low. As a result, while forming a V-shaped cross section, a silicon nitride film can be formed with a high bottom-up property that does not block the opening of the recess 111.

In contrast, in the later stage of the film forming process, the aspect ratio of the recess is low, and the concentration distribution of the active species of the adsorption-inhibiting gas tends to be relatively uniform in the depth direction of the recess. For this reason, the adsorption-inhibiting effect of the N₂ gas that has a large variation in the adsorption-inhibiting effect in the depth direction of the recess, is set to be relatively high. As a result, while forming a V-shaped cross section, a silicon nitride film can be formed with a high bottom-up property that does not block the opening of the recess.

Because the adsorption-inhibiting effect of the N₂ gas is lower than that of the Cl₂ gas, the film formation speed can be improved. That is, productivity of the substrate processing can be improved.

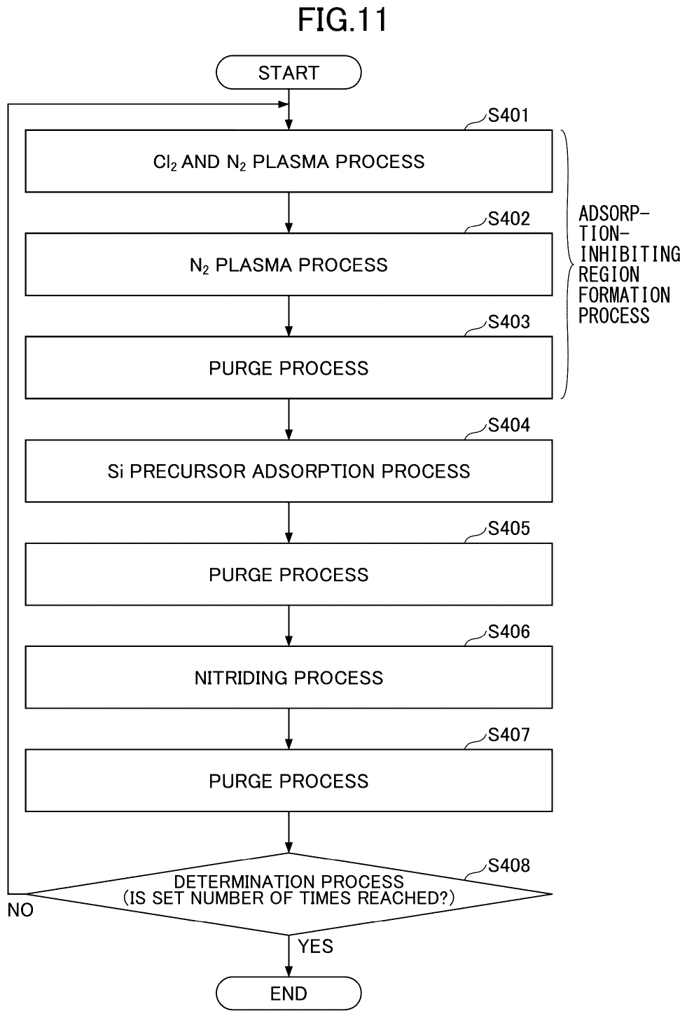

Next, a case where an example of a method of forming a silicon nitride film according to a fourth embodiment is performed by using the above-described film forming apparatus will be described with reference to FIG. 11. FIG. 11 is a flowchart illustrating an example of a method of forming a silicon nitride film according to the fourth embodiment. Here, in the method of forming illustrated in FIG. 11, the processing of the adsorption-inhibiting region formation process is different from that of the method illustrated in FIG. 7. In other respects, the method is the same as the method illustrated in FIG. 7. In the following, points different from the method illustrated in FIG. 7 will be mainly described.

First, the controller 9 carries the wafer W having a trench formed on the surface thereof into the processing container 1. The method of carrying the wafer W into the processing container 1 may be the same as the method illustrated in FIG. 7 described above.

In the method of forming the silicon nitride film according to the fourth embodiment, the adsorption-inhibiting region formation process includes a Cl₂/N₂ plasma process S401, a N₂ plasma process S402, and a purge process S403.

First, the Cl₂/N₂ plasma process S401 is performed. In the Cl₂/N₂ plasma process S401, the wafer W is exposed to a plasma generated from chlorine gas and nitrogen gas to form an adsorption-inhibiting region in the upper portion of the trench and on the surface of the wafer W. In the present embodiment, the controller 9 simultaneously supplies chlorine gas and nitrogen gas from the gas supply 5 into the processing container 1 through the shower head 3, and supplies the RF power to the shower head 3 from the RF power supply 8. As a result, plasma is generated from the chlorine gas and the nitrogen gas in the processing container 1, and active species are supplied onto a base film in the trench formed on the surface of the wafer W. The active species are physically adsorbed or chemically adsorbed on the surface. Because the adsorbed chlorine has a function of inhibiting the adsorption of DCS in a Si precursor adsorption process S404, which will be described later, the region where the chlorine has been adsorbed becomes an adsorption-inhibiting region for the DCS. Similarly to chlorine, nitrogen is also physically adsorbed or chemically adsorbed on the surface. Because the adsorbed nitrogen has a function of inhibiting the adsorption of DCS in the Si precursor adsorption process S404, which will be described later, the region where the nitrogen has been adsorbed becomes an adsorption-inhibiting region for the DCS. Here, the active species can easily reach the surface of the wafer W and the upper portion in the trench, but not as many reach the inner portion of the trench, that is, the lower portion near the bottom portion. In the trench, many of the active species collide with the side wall before reaching the inner portion of the trench, and are adsorbed or deactivated. Therefore, chlorine and nitrogen are adsorbed at a high density on the surface of the wafer W and the upper portion of the trench, but in the lower portion of the trench, a large amount of unadsorbed portion remains and the densities of the adsorbed chlorine and adsorbed nitrogen are relatively low.

The RF power in the Cl₂/N₂ plasma process S401 is preferably smaller than the RF power in a nitriding process S406. This is because, in the Cl₂/N₂ plasma process S401, an adsorbed density gradient of chlorine and nitrogen inside the trench is formed, whereas, in the nitriding process S406, the entire film in the trench is sufficiently nitrided.

The process conditions in the Cl₂/N₂ plasma process S401 may be the same as those in, for example, the Cl₂ plasma process S201 or the N₂ plasma process S203.

Subsequently, the N₂ plasma process S402 is performed. In the N₂ plasma process S402, the wafer W is exposed to a plasma generated from nitrogen gas to form an adsorption-inhibiting region in the upper portion of the trench and on the surface of the wafer W. In the present embodiment, the controller 9 supplies nitrogen gas from the gas supply 5 into the processing container 1 through the shower head 3, and supplies the RF power to the shower head 3 from the RF power supply 8. As a result, plasma is generated from the nitrogen gas within the processing container 1, and active species are supplied onto the base film in the trench formed on the surface of the wafer W. The active species are physically adsorbed or chemically adsorbed to sites where chlorine and nitrogen are not adsorbed in the Cl₂/N₂ plasma process S401. Because the adsorbed nitrogen has a function of inhibiting the adsorption of DCS in the Si precursor adsorption process S404, which will be described later, the region where the nitrogen has been adsorbed becomes an adsorption-inhibiting region for the DCS. Here, the active species can easily reach the surface of the wafer W or the upper portion in the trench, but not as many reach the inner portion of the trench, that is, the lower portion near the bottom portion. In the trench, many of the active species collide with the side wall before reaching the inner portion of the trench, and are adsorbed or deactivated. Therefore, nitrogen is adsorbed at a high density on the surface of the wafer W and the upper portion of the trench, but in the lower portion of the trench, a large amount of unadsorbed portion remains and the density of the adsorbed nitrogen is relatively low.

The RF power in the N₂ plasma process S402 is preferably smaller than the RF power in the nitriding process S406. This is because, in the N₂ plasma process S402, an adsorbed nitrogen density gradient inside the trench is formed, whereas, in the nitriding process S406, the entire film inside the trench is sufficiently nitrided.

The process conditions in the No plasma process S402 may be the same as those in, for example, the N₂ plasma process S203.

When the process proceeds from the Cl₂/N₂ plasma process S401 to the N₂ plasma process S402, for example, only the supply of chlorine gas is stopped while the supply of the RF power is maintained, and the process proceeds to the N₂ plasma process S402. When the process proceeds from the Cl₂/N₂ plasma process S401 to the N₂ plasma process S402, for example, the supply of the RF power, the supply of chlorine gas, and the supply of nitrogen gas may be temporarily stopped, and the process proceeds to the N₂ plasma process S402. When the process proceeds from the Cl₂/N₂ plasma process S401 to the N₂ plasma process S402, for example, the supply of the RF power and the supply of chlorine gas may be temporarily stopped, and the supply of nitrogen gas may be maintained for a certain period of time, and the process proceeds to the N₂ plasma process S402.

For example, a purge process may be performed between the Cl₂/N₂ plasma process S401 and the N₂ plasma process S402.

In the early stage of the film forming process, the partial pressure of the Cl₂ gas is set to be high and the partial pressure of the N₂ gas is set to be low in step S401. Thus, an adsorption-inhibiting region is formed in a state where the adsorption-inhibiting effect by the Cl₂ gas is relatively high. In contrast, in the later stage of the film forming process, the partial pressure of the Cl₂ gas is set to be low and the partial pressure of the N₂ gas is set to be high in step S401. Thus, an adsorption-inhibiting region is formed in a state where the adsorption-inhibiting effect by the Cl₂ gas is relatively high.

In the early stage of the film forming process, the supply time of the N₂ gas in step S402 is decreased. Thus, an adsorption-inhibiting region is formed in a state where the adsorption-inhibiting effect by Cl₂ gas is relatively high. In contrast, in the later stage of the film forming process, the supply time of the N₂ gas in step S402 is increased. Thus, an adsorption-inhibiting region is formed in a state where the adsorption-inhibiting effect by the N₂ gas is relatively high.

Only one of the adjustment parameters in steps S401 and S402 may be changed, or both of the parameters may be changed.

Subsequently, the purge process S403, the Si precursor adsorption process S404, the purge process S405, the nitriding process S406, the purge process S407, and the determination process S408 are performed in this order. The purge process S403, the Si precursor adsorption process S404, the purge process S405, the nitriding process S406, the purge process S407, and the determination process S408 may be the same as the purge process S204, the Si precursor adsorption process S205, the purge process S206, the nitriding process S207, the purge process S208, and the determination process S209 illustrated in FIG. 7.

In this manner, the processes from the Cl₂/N₂ plasma process S401 to the purge process S407 are repeated, and a silicon nitride film is deposited from the bottom side in a state where the opening of the trench is not blocked. Then, while forming a V-shaped cross section, a silicon nitride film can be formed with a high bottom-up property that does not block the opening. As a result, a high-quality silicon nitride film can be embedded in the trench without generating a void.

In the method of forming a silicon nitride film according to the fourth embodiment, in the early stage of the film forming process, the aspect ratio of the recess is high, and the concentration distribution of the active species of the adsorption-inhibiting gas tends to differ in the depth direction of the recess. For this reason, the adsorption-inhibiting effect of the Cl₂ gas is set to be relatively high. As a result, chlorine is adsorbed at a high density on the surface of the wafer W and on the upper portion of the recess, whereas a large amount of unadsorbed portion remains in the lower portion of the recess, and the density of the adsorbed chlorine is low. As a result, while forming a V-shaped cross section, a silicon nitride film can be formed with a high bottom-up property that does not block the opening of the recess 111.

In contrast, in the later stage of the film forming process, the aspect ratio of the recess is low, and the concentration distribution of the active species of the adsorption-inhibiting gas tends to be relatively uniform in the depth direction of the recess. For this reason, the adsorption-inhibiting effect of the N₂ gas that has a large variation in the adsorption-inhibiting effect in the depth direction of the recess, is set to be relatively high. As a result, while forming a V-shaped cross section, a silicon nitride film can be formed with a high bottom-up property that does not block the opening of the recess.

Because the adsorption-inhibiting effect of the N₂ gas is lower than that of the Cl₂ gas, the film formation speed can be improved. That is, productivity of the substrate processing can be improved.

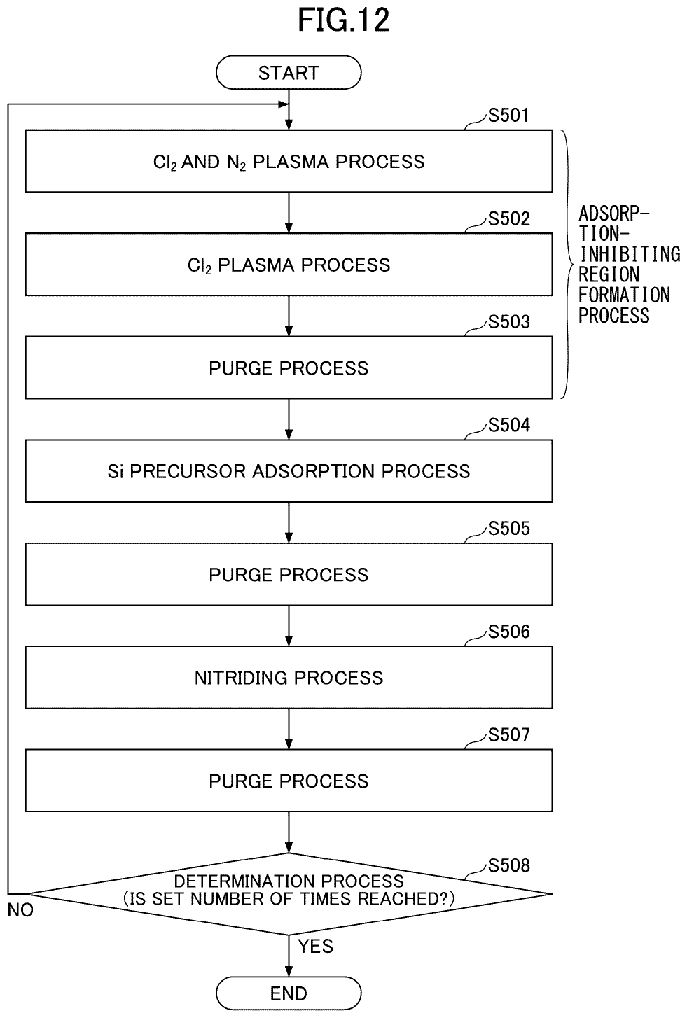

Next, a case where an example of a method of forming a silicon nitride film according to a fifth embodiment is performed by using the above-described film forming apparatus will be described with reference to FIG. 12. FIG. 12 is a flowchart illustrating an example of a method of forming a silicon nitride film according to the fifth embodiment. Here, in the method of forming illustrated in FIG. 12, the processing of the adsorption-inhibiting region formation process is different from that of the method illustrated in FIG. 7. In other respects, the method is the same as the method illustrated in FIG. 7. In the following, points different from the method illustrated in FIG. 7 will be mainly described.

First, the controller 9 carries the wafer W having a trench formed on the surface thereof into the processing container 1. The method of carrying the wafer W into the processing container 1 may be the same as the method illustrated in FIG. 7 described above.

In the method of forming the silicon nitride film according to the fifth embodiment, the adsorption-inhibiting region formation process includes a Cl₂/N₂ plasma process S501, a Cl₂ plasma process S502, and a purge process S503.

First, the Cl₂/N₂ plasma process S501 is performed. The Cl₂/N₂ plasma process S501 may be the same as the Cl₂/N₂ plasma process S401.

Subsequently, the Cl₂ plasma process S502 is performed. In the Cl₂ plasma process S502, the wafer W is exposed to a plasma generated from chlorine gas to form an adsorption-inhibiting region in the upper portion of the trench and on the surface of the wafer W. In the present embodiment, the controller 9 supplies chlorine gas from the gas supply 5 into the processing container 1 through the shower head 3, and supplies the RF power to the shower head 3 from the RF power supply 8. As a result, plasma is generated from the chlorine gas in the processing container 1, and active species are supplied onto a base film in the trench formed on the surface of the wafer W. The active species are physically adsorbed or chemically adsorbed to the sites where chlorine and nitrogen are not adsorbed in the Cl₂/N₂ plasma process S501. Because the adsorbed chlorine has a function of inhibiting the adsorption of DCS in the Si precursor adsorption process S504, which will be described later, the region where the chlorine has been adsorbed becomes an adsorption-inhibiting region for the DCS. Here, the active species can easily reach the surface of the wafer W or the upper portion in the trench, but not as many reach the inner portion of the trench, that is, the lower portion near the bottom portion. In the trench, many of the active species collide with the side wall before reaching the inner portion of the trench, and are adsorbed or deactivated. Therefore, chlorine is adsorbed at a high density on the surface of the wafer W and the upper portion of the trench, but in the lower portion of the trench, a large amount of unadsorbed portion remains and the density of the adsorbed chlorine is relatively low.

The RF power in the Cl₂ plasma process S502 is preferably smaller than the RF power in the nitriding process S506. This is because, in the Cl₂ plasma process S502, an adsorbed chlorine density gradient inside the trench is formed, whereas, in the nitriding process S506, the entire film inside the trench is sufficiently nitrided.

The process conditions in the Cl₂ plasma process S502 may be the same as those in, for example, the Cl₂ plasma process S201.

When the process proceeds from the Cl₂/N₂ plasma process S501 to the Cl₂ plasma process S502, for example, only the supply of nitrogen gas is stopped while the supply of the RF power is maintained, and the process proceeds to the Cl₂ plasma process S502. When the process proceeds from the Cl₂/N₂ plasma process S501 to the Cl₂ plasma process S502, for example, the supply of the RF power, the supply of chlorine gas, and the supply of nitrogen gas may be temporarily stopped, and the process proceeds to the Cl₂ plasma process S502. When the process proceeds from the Cl₂/N₂ plasma process S501 to the Cl₂ plasma process S502, for example, the supply of the RF power and the supply of nitrogen gas may be temporarily stopped, and the supply of chlorine gas may be maintained for a certain period of time, and the process proceeds to the Cl₂ plasma process S502.

For example, a process may be performed between the Cl₂/N₂ plasma process S501 and the Cl₂ plasma process S502.

In the early stage of the film forming process, the partial pressure of the Cl₂ gas is set to be high and the partial pressure of N₂ gas is set to be low in step S501. Thus, an adsorption-inhibiting region is formed in a state where the adsorption-inhibiting effect by the Cl₂ gas is relatively high. In contrast, in the later stage of the film forming process, the partial pressure of the Cl₂ gas is set to be low and the partial pressure of the N₂ gas is set to be high in step S501. Thus, an adsorption-inhibiting region is formed in a state where the adsorption-inhibiting effect by the Cl₂ gas is relatively high.

In the early stage of the film forming process, the supply time of the Cl₂ gas in step S502 is increased. Thus, an adsorption-inhibiting region is formed in a state where the adsorption-inhibiting effect of the Cl₂ gas is relatively high. In contrast, in the later stage of the film forming process, the supply time of the Cl₂ gas in step S502 is decreased. Thus, an adsorption-inhibiting region is formed in a state where the adsorption-inhibiting effect by the N₂ gas is relatively high.

Only one of the adjustment parameters in steps S501 and S502 may be changed, or both of the parameters may be changed.

Subsequently, the purge process S503, the Si precursor adsorption process S504, the purge process S505, the nitriding process S506, the purge process S507, and the determination process S508 are performed in this order. The purge process S503, the Si precursor adsorption process S504, the purge process S505, the nitriding process S506, the purge process S507, and the determination process S508 may be the same as the purge process S403, the Si precursor adsorption process S404, the purge process S405, the nitriding process S406, the purge process S407, and the determination process S408 illustrated in FIG. 11.

In this manner, the processes from the Cl₂/N₂ plasma process S501 to the purge process S507 are repeated, and a silicon nitride film is deposited from the bottom side in a state where the opening of the trench is not blocked. Then, while forming a V-shaped cross section, a silicon nitride film can be formed with a high bottom-up property that does not block the opening. As a result, a high-quality silicon nitride film can be embedded in the trench without generating a void.

In the method of forming a silicon nitride film according to the fifth embodiment, in the early stage of the film forming process, the aspect ratio of the recess is high, and the concentration distribution of the active species of the adsorption-inhibiting gas tends differ in the depth direction of the recess. For this reason, the adsorption-inhibiting effect of the Cl₂ gas is set to be relatively high. As a result, chlorine is adsorbed at a high density on the surface of the wafer W and on the upper portion of the recess, and whereas a large amount of unadsorbed portion remains in the lower portion of the recess, and the density of the adsorbed chlorine is low. As a result, while forming a V-shaped cross section, a silicon nitride film can be formed with a high bottom-up property that does not block the opening of the recess 111.

In contrast, in the later stage of the film forming process, the aspect ratio of the recess is low, and the concentration distribution of the active species of the adsorption-inhibiting gas tends to be relatively uniform in the depth direction of the recess. For this reason, the adsorption-inhibiting effect of the N₂ gas that has a large variation in the adsorption-inhibiting effect in the depth direction of the recess, is set to be relatively high. As a result, while forming a V-shaped cross section, a silicon nitride film can be formed with a high bottom-up property that does not block the opening of the recess.

Because the adsorption-inhibiting effect of the N₂ gas is lower than that of the Cl₂ gas, the film formation speed can be improved. That is, productivity of the substrate processing can be improved.

The various processes of forming the adsorption-inhibiting region have been described above with reference to FIGS. 2, 7, 9, 11, and 12, but the disclosure is not limited thereto. For example, in the flow illustrated in FIG. 7, the order of step S201 and step S203 may be changed, and the Cl₂ plasma process may be performed after the N₂ plasma process is performed. In the flow illustrated in FIG. 11, the order of step S401 and step S402 may be changed, and the Cl₂/N₂ plasma process may be performed after the N₂ plasma process is performed. In the flow illustrated in FIG. 12, the order of step S501 and step S502 may be changed, and the Cl₂/N₂ plasma process may be performed after the Cl₂ plasma process is performed.

The adsorption-inhibiting region may be formed by combining the Cl₂ plasma process, the N₂ plasma process, and the Cl₂/N₂ plasma process. For example, after the Cl₂ plasma process is performed, the N₂ plasma process may be performed, followed by the Cl₂ plasma process. After the N₂ plasma process is performed, the Cl₂ plasma process may be performed, followed by the N₂ plasma process. Further, for example, after the Cl₂ plasma process is performed, the Cl₂/N₂ plasma process may be performed, followed by the Cl₂ plasma process. After the N₂ plasma process is performed, the Cl₂/N₂ plasma process may be performed, followed by the N₂ plasma process. The combination of the Cl₂ plasma process, the N₂ plasma process, and the Cl₂/N₂ plasma process is not limited to the above, and may include a combination of three or more processes.

In this case, in the Cl₂ plasma process, the adsorption-inhibiting region may be formed in a state where the adsorption-inhibiting effect of the Cl₂ gas is relatively high in the early stage of the film forming process, and the adsorption-inhibiting region may be formed in a state where the adsorption-inhibiting effect of the Cl₂ gas is relatively low (a state where the adsorption-inhibiting effect of the N₂ gas is relatively high) in the later stage of the film forming process. In the N₂ plasma process, the adsorption-inhibiting region may be formed in a state where the adsorption-inhibiting effect of the N₂ gas is relatively low (a state where the adsorption-inhibiting effect of the Cl₂ gas is relatively high) in the early stage of the film forming process, and the adsorption-inhibiting region may be formed in a state where the adsorption-inhibiting effect of the N₂ gas is relatively high in the later stage of the film forming process. In the Cl₂/N₂ plasma process, the adsorption-inhibiting region may be formed in a state where the adsorption-inhibiting effect of the Cl₂ gas is relatively high in the early stage of the film forming process, and the adsorption-inhibiting region may be formed in a state where the adsorption-inhibiting effect of the N₂ gas is relatively high in the later stage of the film forming process.

The method of forming a silicon film according to the embodiment may further include a modification process. The modification process is performed, for example, at least after the process of forming the adsorption-inhibiting region, after the process, or after the Si precursor adsorption nitriding process. In the modification process, the wafer W is exposed to a plasma generated from hydrogen gas to modify the Si-containing layer and the SiN film. In the present embodiment, the controller 9 supplies hydrogen gas from the gas supply 5 into the processing container 1 through the shower head 3, and supplies the RF power to the shower head 3 from the RF power supply 8. As a result, plasma is generated from the hydrogen gas in the processing container 1, and active species, such as hydrogen radicals and hydrogen ions, are supplied to the surface of the wafer W and into the trench. As a result, the Si-containing layer is modified. The modification of the Si-containing layer includes, for example, removing halogens contained in the Si-containing layer. The modification of the Si-containing layer also includes removing halogens and excess NHₓ groups in the SiN film, in the second and subsequent cycles. By removing halogens and excess NHₓ groups, for example, the wet etch rate can be improved.

The embodiments disclosed herein are exemplary in all respects and not restrictive. The above-described embodiments may be omitted, replaced, or modified in various forms without departing from the scope and spirit of the appended claims.

In the above-described embodiments, the cases where the film forming apparatus is a capacitively coupled plasma apparatus have been described, but the present disclosure is not limited thereto. For example, a plasma apparatus using inductively coupled plasma, surface wave plasma (microwave plasma), magnetron plasma, remote plasma, or the like as a plasma source may be used.

In the above-described embodiments, the cases where the film forming apparatus is a single-wafer-type apparatus for processing wafers one by one have been described, but the present disclosure is not limited thereto. For example, the film forming apparatus may be a batch-type apparatus that processes a plurality of wafers at once. For example, the film forming apparatus may be a semi-batch-type apparatus that causes a plurality of wafers placed on a rotary table in a processing container to revolve by the rotary table such that the wafers sequentially pass through a region to which a first gas is supplied and a region to which a second gas is supplied, thereby processing the wafers. For example, the film forming apparatus may be a multi-single-wafer-type film forming apparatus that includes a plurality of mounting tables in a single processing container.

The present application claims priority to Japanese Patent Application No. 2022-21561, filed Feb. 15, 2022, with the Japanese Patent Office, the contents of which are incorporated herein by reference in their entirety.

### DESCRIPTION OF THE REFERENCE NUMERAL

1 Processing Container
5 Gas Supply
9 Controller

1. A method of forming a silicon nitride film in a recess formed on a surface of a substrate, the method comprising:
forming an adsorption-inhibiting region by exposing the substrate to a plasma generated from an adsorption-inhibiting gas containing at least one of a halogen gas or a non-halogen gas;
adsorbing a silicon-containing gas to a region other than the adsorption-inhibiting region; and
forming a silicon nitride film by exposing the substrate to which the silicon-containing gas is adsorbed to a plasma generated from a nitrogen-containing gas, wherein
a cycle including the forming of the adsorption-inhibiting region, the adsorbing of the silicon-containing gas, and the forming of the silicon nitride film is repeated, and
in the forming of the adsorption-inhibiting region, with an increase in a count of repetition of the cycle, a state in which adsorption inhibition by the halogen gas is high changes to a state in which adsorption inhibition by the non-halogen gas is high.

2. The method of forming a silicon nitride film according to claim 1, wherein
the forming of the adsorption-inhibiting region includes: exposing the substrate to a plasma generated from the halogen gas, and, with the increase in the count of repetition of the cycle, exposing the substrate to a plasma generated from the non-halogen gas.

3. The method of forming a silicon nitride film according to claim 1, wherein
the forming of the adsorption-inhibiting region includes: exposing the substrate to a plasma generated from the halogen gas, and exposing the substrate to a plasma generated from the non-halogen gas.

4. The method of forming a silicon nitride film according to claim 3, wherein in the forming of the adsorption-inhibiting region, with the increase in the count of repetition of the cycle, power supplied to generate the plasma of the halogen gas is decreased.

5. The method of forming a silicon nitride film according to claim 3, wherein in the forming of the adsorption-inhibiting region, with the increase in the count of repetition of the cycle, a gas supply time of the halogen gas is decreased.

6. The method of forming a silicon nitride film according to claim 1, wherein the forming of the adsorption-inhibiting region includes: exposing the substrate to a plasma generated from both the halogen gas and the non-halogen gas.

7. The method of forming a silicon nitride film according to claim 6, wherein in the forming of the adsorption-inhibiting region, with the increase in the count of repetition of the cycle, a partial pressure of the halogen gas is decreased.

8. The method of forming a silicon nitride film according to claim 6, wherein
the forming of the adsorption-inhibiting region includes: exposing the substrate to the plasma generated from both the halogen gas and the non-halogen gas, and exposing the substrate to a plasma generated from the halogen gas or the non-halogen gas.

9. The method of forming a silicon nitride film according to claim 1, wherein
the halogen gas is chlorine gas, and
the non-halogen gas is nitrogen gas.

10. The method of forming a silicon nitride film according to claim 1, further comprising modifying the substrate by exposing the substrate to a plasma generated from a hydrogen gas.

11. The method of forming a silicon nitride film according to claim 10, wherein the modification process is preformed after at least one of the forming of the adsorption-inhibiting region, the adsorbing of the silicon-containing gas, or the forming of the silicon nitride film.

12. A film forming apparatus comprising:
a processing container configured to accommodate a substrate having a recess formed on a surface thereof;
a gas supply configured to supply an adsorption-inhibiting gas, a silicon-containing gas, and a nitrogen-containing gas into the processing container; and
a controller, wherein
the adsorption-inhibiting gas contains a halogen gas and a non-halogen gas,
the controller is configured to control the gas supply to repeatedly perform a cycle including:
forming an adsorption-inhibiting region by exposing the substrate to a plasma generated from the adsorption-inhibiting gas;
adsorbing the silicon-containing gas to a region other than the adsorption-inhibiting region; and
forming a silicon nitride film by exposing the substrate to which the silicon-containing gas is adsorbed to a plasma generated from the nitrogen-containing gas, and
in the forming of the adsorption-inhibiting region, with an increase in a count of repetition of the cycle, a state in which adsorption inhibition by the halogen gas is high changes to a state in which adsorption inhibition by the non-halogen gas is high.
